(19) United States
(12) Patent Application Publication
(10) Pub. No.: US 2022/0267927 A1
(43) Pub. Date: Aug. 25, 2022

(54) QPM STRUCTURES BASED ON OPTIMIZED OP-GaAs TEMPLATES WITHOUT MBE ENCAPSULATING LAYER

(71) Applicant: Government of the United States, as represented by the Secretary of the Air Force, Wright-Patterson AFB, OH (US)

(72) Inventors: Shivashankar R. Vangala, Mason, OH (US); Vladimir Tassev, Beavercreek, OH (US)

(21) Appl. No.: 17/181,201

(22) Filed: Feb. 22, 2021

(51) Int. Cl. C30B 25/20; H01L 21/02; C30B 29/42; C30B 29/44; C30B 25/16

(52) U.S. Cl. CPC C30B 25/20; H01L 21/02395; H01L 21/02433; H01L 21/02543; H01L 21/02546; H01L 21/02409; H01L 21/0262; C30B 29/42; C30B 29/44; C30B 25/165

(57) ABSTRACT

A method of performing heteroepitaxy comprises exposing an OP-GaAs template in an HVPE reactor to a carrier gas, a first precursor gas, a second precursor gas (2pg), a Group II element, and a third precursor gas (3pg), to form an epitaxial growth of one of GaAs, GaP, and GaAsP directly on the OP-GaAs template; wherein the carrier gas is H₂, wherein the first precursor is HCl, the Group II element is Ga; and wherein the second (V or VI group) precursor is one or more of AsH₃ (arsine) and PH₃ (phosphine), and the third precursor is one or more of PH₃ and AsH₃. For an epitaxial growth of GaAsP, the method may further comprise flowing the second and third precursors through the HVPE reactor at a 2pg:3pg ratio of about 1:0; heating the OP-template to 500° C.-900° C.; and gradually changing the 2pg:3pg ratio toward 0:1 over time.

Pursuant to 37 C.F.R. §1.78(a)(4), this application claims the benefit of and priority to prior filed co-pending Provisional Application Ser. No. 62/681,155, filed 6 Jun. 2018; co-pending Provisional Application Ser. No. 62/692,930, filed 2 Jul. 2020; co-pending Non-Provisional Application Ser. No. 16/201,446, filed 27 Nov. 2018; co-pending Non-Provisional Application Ser. No. 16/447,677, filed 20 Jun. 2019; and co-pending Non-Provisional Application Ser. No. 17/094,878, filed 11 Nov. 2020, which are expressly incorporated herein by reference.

### RIGHTS OF THE GOVERNMENT

The invention described herein may be manufactured and used by or for the Government of the United States for all governmental purposes without the payment of any royalty.

### FIELD OF THE INVENTION

The present invention relates generally to the growth of quasi-phase matching (QPM) structures and, more particularly, to the growth of QPM structures on OP-GaAs templates without an MBE encapsulating layer.

### BACKGROUND OF THE INVENTION

“OP” means orientation-patterned. An OP-template is a substrate that is patterned in such a way that it comprises parallel domains with alternating opposite crystal polarities. Thick growth on an OP-template aims to keep the template's domains properly propagating through one or more of the subsequent layers. Prior art OP template preparation starts with the deposition of an inverted layer through an all-epitaxial GaAs/Ge/GaAs (or GaP/Si/GaP) approach. In such cases molecular beam epitaxy (MBE) of a thin intermediate non-polar Ge (or Si) layer (a first MBE layer) on the substrate is followed by a second MBE growth of a thin top layer of the same material as the substrate (GaAs or GaP) conducted under specific growth conditions. The experimentally-determined growth conditions lead to the reversal (inversion) of the GaAs (or GaP) layer's (second MBE layer) crystallographic orientation with respect to the crystallographic orientation of the underlying GaAs (or GaP) substrate (FIGS. 1A and 1B). A third step in this process applies photolithography and selective chemical etching to allow partial access not only to the top (inverted) GaAs (or GaP) layer (second MBE layer), but also to the GaAs (or GaP) substrate underneath, producing a template having regions with alternating and opposite crystallographic polarities (orientations), i.e. an orientation-patterned template, as shown in FIG. 1C. After this step, a further growth using MBE (a third MBE layer) is also performed to make sure that the alternating domains will propagate in the growing layer. This third MBE layer, i.e. encapsulating layer, also ensures that the surface will have an “epi-ready” quality, i.e. a smoother surface morphology than the one left after the patterning. This further regrowth, however, further increases the price of the OP template, because after the previous patterning the template must be introduced into the MBE chamber again for growth of the encapsulating layer. Only after all these steps are completed is the template now ready to be used for thick regrowth by HVPE to produce 500 μm or thicker QPM structures, e.g. for nonlinear optical frequency conversion.

QPM structures based on OP-GaAs are the current state-of-the art for nonlinear frequency conversion devices, however, its strong two-photon absorption (2PA) at wavelengths below 1.7 μm deprives GaAs of using a number of commercially-available high-power pump laser sources in the range of 1-1.7 μm, including those conventional sources radiating at 1.55 μm and which are broadly used in optical telecommunications. As an alternative, GaP with similar nonlinear properties offers some important advantages over GaAs such as excellent thermal properties, dispersion of the refractive index that would allow pumping with shorter wavelengths through a pattern with wider domains, and especially its lower 2PA. However, GaP suffers from poor material quality and associated growth problems in developing thick QPM structures. The current known state-of-the-art is for the growth of GaP, GaAs, and, recently, their GaAsP ternaries on OP-GaAs or OP-GaP templates with a preliminary MBE deposition of a thin Ge (in case of GaAs) or Si (in case of GaP) film deposited on the GaAs or a GaP wafer. As explained above, the role of this thin non-polar Si or Ge layer is only to “wash-off' or conceal the polarity of the underlying material and, thus, to provide the conditions for the crystal polarity of the subsequent GaP or GaAs inverted layer to be alternated by applying suitable growth conditions. The current prior art, as explained above, after patterning the inverted layer, conducts another MBE growth (a third MBE layer) of a thin encapsulating layer from the same material as the substrate, i.e. a GaAs encapsulating layer with a GaAs substrate, or a GaP encapsulating layer with a GaP substrate. Bearing in mind the aforementioned advantages of the encapsulation layer and, more precisely, its role in accommodating the following thick hydride vapor phase epitaxial (HVPE), a direct HVPE growth of GaP or GaAs on the inverted MBE-grown and patterned GaAs or GaP layer (i.e. on the OP-GaAs or OP-GaP template) without the preliminary deposition of an encapsulating layer is not obvious and it's not simple, since it requires accommodating two very different growth methods, MBE and HVPE, to each other when the MBE layer has a relatively rough surface due to the patterning. The novelty of such an approach for developing QPM structures for frequency conversion in the mid and longwave infrared (MLWIR) without an encapsulating layer becomes even greater taking into account that the HVPE growth can be performed homo-epitaxially (i.e. GaP/GaP or GaAs/GaAs) or hetero-epitaxially (i.e. GaP/GaAs or GaAs/GaP). What is desired is a method that eliminates the MBE growth of the encapsulating layer, which would not only significantly reduce the price of the OP template but also, as it will be shown in the following text, would significantly improve the layer surface quality.

### SUMMARY OF THE INVENTION

As explained above, it is desired to find a way to combine the thick HVPE growth of a QPM structure on an MBE-grown and patterned inverted layer, i.e. the HVPE growth on an OP-template, but skipping or eliminating the MBE deposition step of an encapsulating layer. Accordingly, the subject of this disclosure is to combine two different growth techniques, MBE and HVPE, which are different by their natures, and not to the mere combining of two materials; this can be done homo- or heteroepitaxially. OP-GaAs templates are suggested as the best candidate due to their better quality. The HVPE grown materials may be GaP, GaAs, their ternaries, and some other close matching materials, e.g. ZnSe.

The fabrication of the conventional OP-GaAs templates and the following HVPE growth includes epitaxial growth on a commercially-procured OP-GaAs template. This commercially-procured OP-GaAs template includes several features which are not claimed:

the deposition of a thin layer from a non-polar material which in case of GaAs is a Ge layer on the GaAs substrate which has the first polarity;

MBE growth of a thin GaAs layer with the opposite polarity in regards to the polarity of the GaAs substrate, i.e. an inverted GaAs layer on the Ge non-polar layer;

patterning of the template to give access to both polarities as the patterning consists in, first, covering the inverted layer with a mask and, second, etching of the underlying inverted and nonpolar layers through the mask's apertures until we get access to the GaAs substrate with the first polarity; and

deposition of an MBE encapsulating GaAs layer on the pattern.

Each of the four features presented above are provided from the vendor, e.g. BAE Systems, Inc.

The present invention performs HVPE growth of OP-GaAs, OP-GaP, or OP-ZnSe on simplified OP-GaAs templates at which the deposition of the encapsulating GaAs layer is omitted. Thus, these simplified OP-GaAs templates are without an encapsulating GaAs layer.

Contrary to the conventional method described above, the present invention may be employed to perform the patterning in-house (which is similar to the patterning that the vendor, typically, performs) but to skip the deposition of a thin MBE OP-GaAs encapsulating layer, proceeding directly to a thick HVPE growth on the non-encapsulated OP-GaAs template. Such HVPE growth may be performed homoepitaxially, if the goal is to grow OP-GaAs on OP-GaAs templates, or heteroepitaxially, if the goal is to grow OP-GaP or OP-ZnSe on the same OP-GaAs template, which is possible due to the relatively small lattice mismatch between GaP and ZnSe with GaAs.

Even though the role of the deposition of an MBE encapsulating layer on the patterned GaAs surface of the inverted layer is to smooth the pattern's surface, and thus to facilitate the following HVPE growth, the omission of this encapsulating layer, surprisingly, results in even smoother surface morphology of the HVPE layer. Without being bound by theory, it is thought that a rougher surface of the pattern facilitates the HVPE growth by providing a more uniformly-distributed initial nucleation of HVPE layer. The prior art understood that omission of the MBE layer would be a disadvantage, but it was discovered that the opposite is true.

The present invention overcomes the foregoing problems and other shortcomings, drawbacks, and challenges of semiconductor growth on OP-GaAs templates. While the invention will be described in connection with certain embodiments, it will be understood that the invention is not limited to these embodiments. To the contrary, this invention includes all alternatives, modifications, and equivalents as may be included within the spirit and scope of the present invention.

According to one embodiment of the present invention a method of performing heteroepitaxy comprises exposing an OP-GaAs template in an HVPE reactor to a carrier gas, a first precursor gas, a Group II element, a second precursor gas (2pg), and a third precursor gas (3pg) ((2pg) and (3pg) provide Group V element), to form an epitaxial growth of one of GaAs, GaP, and GaAsP directly on the OP-GaAs template; wherein the carrier gas is H₂ , wherein the first precursor gas is HCl, the Group II element is Ga (the first precursor gas and Group II element form GaCl); and wherein the second precursor gas (2pg) and the third precursor gas (3pg) are AsH₃ (arsine), or PH₃ (phosphine), or their mixture, AsH₃+PH₃.

When the second precursor gas (2pg) is AsH₃, the epitaxial growth is GaAs, and because the template is an OP-GaAs template, the epitaxial growth is OP-GaAs. When the second precursor gas (2pg) is PH₃, the epitaxial growth is GaP, and because the template is an OP-GaAs template, the epitaxial growth is OP-GaP. When the second precursor gas (2pg) is a combination (a mixture) of AsH₃ and PH₃, the epitaxial growth is GaAsP.

For an epitaxial growth of GaAsP, flowing the second and third precursor gases of AsH₃ (arsine) and PH₃ (phosphine), respectively, through the HVPE reactor at a 2pg:3pg ratio of about 1:0; heating the OP-template to 500° C.-900° C.; and gradually changing the 2pg:3pg ratio toward 0:1 over a time period of 1 min-10 hours, to achieve the desired As:P ratio in the grown GaAsP. The OP-template may be heated to 700° C.-740° C.

For an epitaxial growth of GaAs, flowing the second and third precursor gases of AsH3 (2pg and 3pg are both arsine) through the HVPE reactor; heating the OP-template to 500° C.-900° C.; and maintaining the growth conditions for a desired time period. The OP-template may be heated to 700° C.-740° C.

For an epitaxial growth of GaP, flowing the second and third precursor gases of PH₃ (2pg and 3pg are both phosphine) through the HVPE reactor; heating the OP-template to 500° C.-900° C.; and maintaining the growth conditions for a desired time period. The OP-template may be heated to 700° C.-740° C.

According to a variation of the first embodiment, in order to form an epitaxial growth of GaAsP on the OP-GaAs template, flowing a second and a third precursors gases, AsH₃ and PH₃, through the HVPE reactor is necessary. At the same time, it is recommended that the 2pg:3pg ratio, i.e. the AsH₃:PH₃, ratio starts at about 1:0. Thus, at the beginning, the growing layer on the GaAs substrate or template will be mostly GaAs (or OP-GaAs). The further increase of PH₃ in the mixture will provoke a gradual conversion of the growing GaAs layer into a GaAsP layer, and its chemical composition may be kept constant by keeping the AsH₃:PH₃ ratio (2pg:3pg) at a defined value. A further increase of PH₃ at the expense of AsH₃ towards the 0:1 ratio (which may occur over a period of 1 min to 10 hours) will eventually lead to converting the GaAsP ternary layer into a pure GaP layer.

The OP-template during this process may be heated to 500° C.-900° C. However, to avoid the thermal decomposition of the substrate/template it is recommended above 500° C. that the template is kept in an AsH₃, PH₃, or AsH₃+PH₃ atmosphere.

According to a second embodiment of the present invention, a method of performing heteroepitaxy comprises exposing an OP-GaAs template in an HVPE reactor to a carrier gas, a first precursor gas, a Group II, and a second and a third precursor gas to form an epitaxial growth of ZnSe directly on the OP-GaAs template; wherein the carrier gas is H₂, wherein the first precursor is HCl, the Group II element is Zn (the HCl and Zn form ZnCl); and wherein the second precursor is H₂Se (hydrogen selenide). Because the template is an OP-GaAs template, the epitaxial growth is OP-ZnSe.

The OP-template may be heated to 500° C.-850° C. but, again, to avoid the thermal decomposition of the substrate/template it is recommended above 500° C. the template is kept in an AsH₃, H₂Se, or AsH₃+H₂Se atmosphere. According to a third embodiment of the present invention, an epitaxial structure comprises an (orientation-patterned) OP-GaAs template having a face of exposed OP-GaAs; and an epitaxially-grown layer of a semiconductor directly on the exposed OP-GaAs of the OP-GaAs template, wherein the semiconductor is one or more of OP-GaAs, OP-GaP, OP-GaAsP, and OP-ZnSe. This arrangement is unique in that the epitaxially-grown semiconductor is grown directly on the exposed OP-GaAs of the OP-GaAs template.

Additional objects, advantages, and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated in and constitute a part of this specification, illustrate embodiments of the present invention and, together with a general description of the invention given above, and the detailed description of the embodiments given below, serve to explain the principles of the present invention. The patent or application file contains at least one drawing executed in color. Copies of this patent or patent application publication with color drawing(s) will be provided by the Office upon request and payment of the necessary fee.

FIGS. 1A-1C present schematic views of OP-template development: FIG. 1A presents a (100) GaAs substrate that is used as one of the orientations; FIG. 1B presents a thin Ge layer grown by MBE followed by a GaAs layer whose orientation is inverted with respect to the substrate; and FIG. 1C presents QPM gratings that are defined using photolithography and chemical etching to reveal alternating domains.

FIG. 2 presents the prior art and new steps of the method for thick HVPE growth on a template.

FIG. 3 is a schematic of an HVPE reactor showing the reactor components and the template. The inset is a part of the reactor showing the post-growth templates and the parasitic nucleation which is behind the templates.

FIG. 4A depicts thick HVPE growth of OP-GaAs grown on OP-GaAs template without encapsulating layer.

FIG. 4B depicts GaP on an OP-GaAs template without an encapsulating layer.

FIG. 4C depicts OP-GaP grown on an OP-GaAs template with an encapsulating layer.

FIG. 4D depicts OP-GaAsP grown on an OP-GaAs template without an encapsulating layer.

FIG. 5A depicts a cross section image of an area near the top surface of an OP-GaAsP layer grown on an OP-GaAs template without an encapsulating layer.

FIG. 5B depicts a Keyence laser scan of the top surface image of the sample shown in FIG. 5A (growth on an OP-GaAs template without an encapsulating layer). FIG 5C presents a cross section of an area near the top surface of an OP-GaAsP layer grown on a conventional commercial OP-GaAs template with an encapsulating layer.

FIGS. 6A and 6B depict ZnSe grown on a GaAs substrate (FIG. 6A is a top surface image and FIG. 6B is a cross section image).

FIGS. 6C and 6D depict OP-ZnSe grown on an OP-GaAs template (FIG. 6C is a top surface image and FIG. 6D is a cross section image).

FIG. 7 illustrates a schematic of an optical parametric oscillator (OPO).

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been

enlarged or distorted relative to others to facilitate visualization and clear understanding. In particular, thin features may be thickened, for example, for clarity or illustration.

### DETAILED DESCRIPTION OF THE INVENTION

The focus of this invention is the homo- or heteroepitaxial growth by the HVPE technique of semiconductor materials directly on the patterned surface of the ‘inverted layer’ of an orientation-patterned template, eliminating the deposition of an additional encapsulating layer prior to the HVPE growth. The inverted layer may be of the same material as the substrate but with the opposite crystallographic orientation, i.e. a layer with inverted polarity in regards to the polarity of the substrate. This method is contrasted with prior art methods where the grown, inverted layer may also be of the same or different material as the substrate, but the prior art version includes the preliminary MBE deposition of layers, including an MBE-deposited “encapsulating layer” which may be from the same or different material as the inverted layer material. The similarities in this disclosure and in the prior art are that in both cases an MBE layer of a non-polar material (e.g. Si, Ge, etc.) is first deposited directly on the template or substrate in order to “wash-off' or mask the polarity of the substrate material in order to provide conditions for growing the inverted layer having polarity opposite of the template or substrate. In the new method disclosed herein, however, we have eliminated the uppermost MBE-deposited layer, i.e. the encapsulating layer, of the prior art, which provides a tremendous savings of time and money. At the same time, the quality of the HVPE-grown layers is improved.

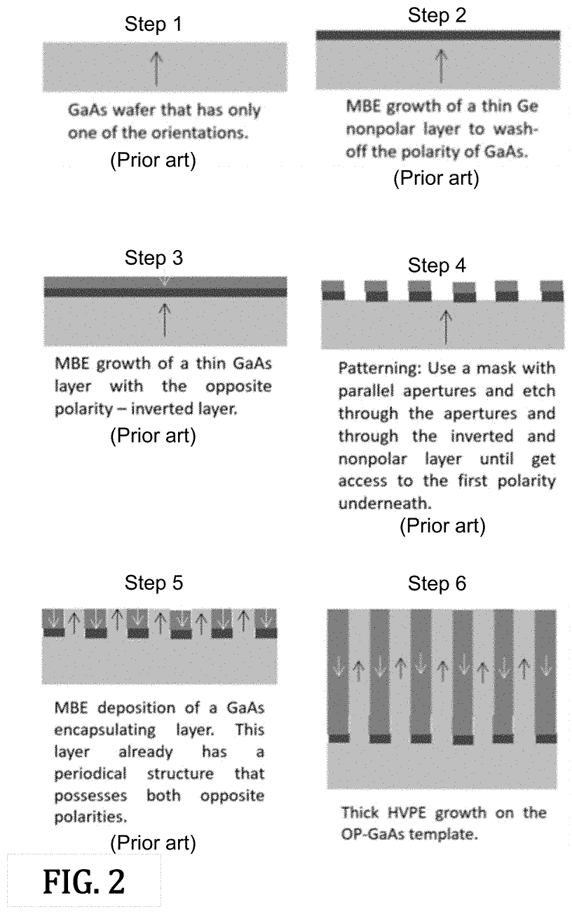

FIG. 2 presents the prior art and new method steps for thick growth on an OP-GaAs template. There are at least two variations described. In the first case, the growth of commercial OP-templates, the vendor performs the first five steps, while we perform the sixth step for thick HVPE growth as described herein. The price of a commercial template is about $9,500.

In the second case, the vendor performs only steps 1, 2, and 3. GaAs wafers prepared according to this method cost only about $4,300. The GaAs template, however, is not yet an OP-template. At this stage the template has only the inverted layer deposited (step 3) on the non-polar layer. According to the method described herein, we perform steps 4 and 6 in-house, skipping step 5. The disclosed method grows (via HVPE) a thick growth directly on the structure patterned in step 4, the thick HVPE layer.

Development of orientation patterned (OP) GaAs, GaP, and GaAsP quasi-phase matching structures is disclosed. The structures were grown by homo- and

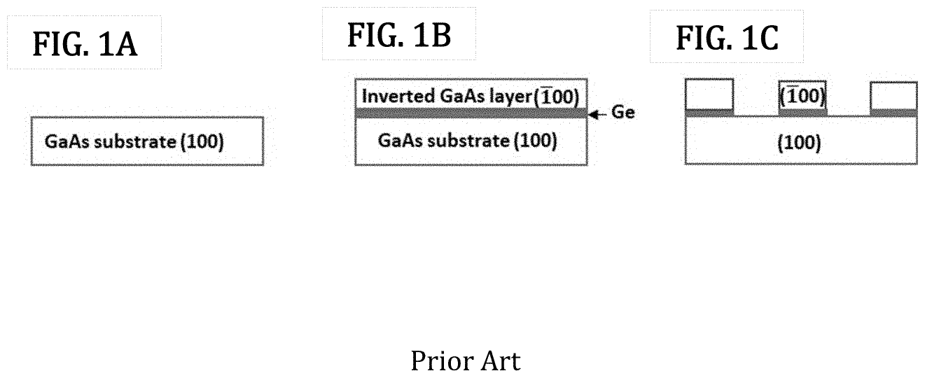

heteroepitaxy directly on the surface of the inverted layer after its patterning (see FIG. 1C) of an OP-GaAs template; in accordance with our new method, the deposition of an encapsulating MBE layer is omitted. Special interest is paid to the heteroepitaxy of GaP on higher quality and lower price OP-GaAs templates, as well as the growth of GaAsP on the same OP-GaAs templates—the latter case represents an even stronger heteroepitaxial case due to the smaller lattice mismatch between GaAsP and GaAs compared to the lattice mismatch between GaP and GaAs. In addition, the ternary GaAsP material may combine the best nonlinear properties of GaAs and GaP binary compounds to overcome the large 2PA in GaAs, the lower nonlinear susceptibility and poor material quality of GaP and the associated growth problems to yield a better QPM material for frequency conversion in the mid- and long-infrared region.

The 0.3-1.0 mm thick OP-GaAs, OP-GaP, and OP-GaAsP QPM structures have been repeatedly grown by hydride vapor phase epitaxy (HVPE) on the OP-GaAs templates without an encapsulating layer, and have demonstrated excellent domain fidelity, i.e. vertical propagation of the domain while maintaining constant domain widths for both orientations, with less than 5% deviation from the nominal width size throughout the whole layer thickness. The disclosed templates are OP-GaAs templates; the disclosed templates have eliminated the requirement for molecular beam epitaxy regrowth of an encapsulating layer. Prior art methods taught that growth of this encapsulating layer was necessary for achieving the alternating crystal domains.

The disclosed GaAs, GaP, and GaAsP QPM structures use OP-GaAs templates without an MBE encapsulating layer, with HVPE homo- and heteroepitaxial growth directly on the patterned surface of the inverted layer of the templates.

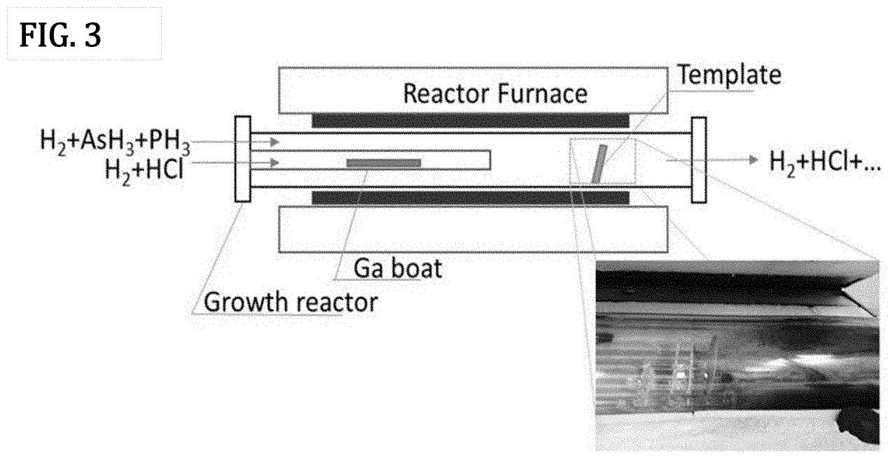

Thick growth of GaAs, GaP, and GaAsP was demonstrated, first, on GaAs and GaP substrates (the substrates are not yet orientation-patterned (OP)) and on OP-GaAs templates, both with and without an MBE encapsulating layer, using the HVPE growth process discussed below. The HVPE homo- and heteroepitaxial growths were performed in a horizontal hot-wall quartz reactor on GaP (100) and GaAs (100) substrates cut 4° off-axis towards (111)B. The HVPE reactor schematic is shown in FIG. 3. The growth conditions are such that the reactor pressure is maintained below 10 Torr for the growth runs while the substrate growth temperatures were in the range of 700-740 ° C. Arsine (AsH₃), phosphine (PH₃), Ga, and hydrogen chloride (HCl) were used as precursors, for the growth of GaAsP, while high purity hydrogen (H₂) was used as the carrier gas with a total gas flow of less than 250 sccm. Arsine (AsH₃), Ga, and hydrogen chloride (HCl) were used as precursors for the growth of GaAs. Phosphine (PH₃), Ga, and hydrogen chloride (HCl) were used as precursors for the growth of GaP. Flow rates for HCl and AsH₃ and/or PH₃ were varied during the growth to optimize the growth conditions and to obtain the desired layer quality and, in the case of GaAsₓP₁₋ₓ, the desired ternary composition x, which was in the range 0.07-0.93. The growth conditions and reactor configuration used for GaAsP growth are similar to that used for the growth of GaAs and GaP materials and are reported elsewhere, i.e. substrate temperature between 700-740 ° C., reactor pressure under 10 Torr and total gas flow within 250 sccm. It should be noted that the HVPE growth process is a close-to-equilibrium process under mass transport limited conditions and yields significantly higher growth rates compared to metal-organic vapor phase epitaxy (MOVPE) and molecular beam epitaxy (MBE) that are the far-from-equilibrium growth processes. (Note: a mass transport limited or mass transport controlled process is a growth process in which the growth rate is determined by the diffusion rate of the gas species approaching the substrate through the so-called boundary layer which is adjacent to the substrate surface.)

Growth of the ternary GaAsP is possible on both substrate materials, i.e. GaAs and GaP, as well as OP-GaAs templates; the lattice mismatch is smaller with each of them compared to the lattice mismatch between GaP and GaAs. The desired composition of the ternary—whether closer to the composition of GaP (more phosphorus) or GaAs (more arsenic)—determines which substrate is best for the growth of the ternary, i.e. the GaAsP with more P may be more favorably grown on a GaP substrate, while GaAsP with more As may be more favorably grown on an OP-GaAs template. The GaAsP ternary permits the combination of the nonlinear optical properties of both GaAs and GaP into a single material, i.e. a ternary that has the higher nonlinear susceptibility of GaAs and the lower 2PA of GaP. At the same time, at certain compositions the GaAsP ternaries may allow pumping with shorter wavelengths with readily available laser sources throughout patterns with wider domains, which may be grown more easily by HVPE. Thicknesses of the GaAsP layer have been demonstrated up to˜500 μm. Growth rates exceeding 100 μm/h are routinely achieved during these heteroepitaxial growths. A major practical goal is to demonstrate frequency conversion in this material with material's improved optical properties.

SEM and EDS analyses may be used to semi-quantitatively determine the atomic composition for P, Ga, and As in GaAsP. For example, the observed optical transmission measurements indicated that transmission through the GaAsP ternary remained between those for GaAs and GaP and, importantly, that the undesirable additional absorption

band between 2-4 μm that persistently exists in GaP is not present in the grown GaAsP ternary samples.

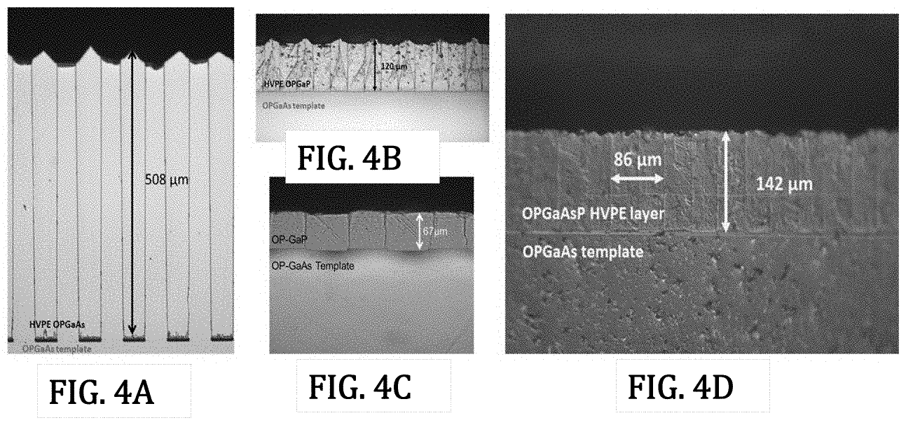

Once the growth of GaAs, GaP, and GaAsP using plain GaAs or GaP substrates was demonstrated, growths of OP-GaAs on OP-GaAs templates without the encapsulating layer (FIG. 4A) were conducted. Next, OP-GaP was grown on OP-GaAs templates with an encapsulating layer (FIG. 4C) and without an encapsulating layer (FIG. 4B). Growths of OP-GaAsP on OP-GaAs templates without an encapsulating layer (FIG. 4D) were also conducted. As one can see from these cross-section images (FIGS. 4A-4D), the domain fidelity throughout the total thickness of the grown layer is consistent on the OP-templates without encapsulating layer.

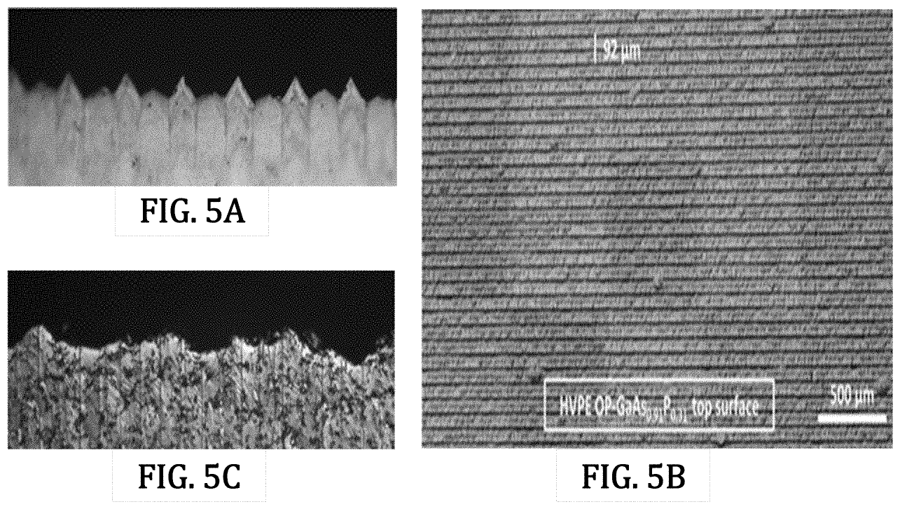

In addition, the growths of, for example, GaAsP on OP-GaAs template without an encapsulating layer results not only in excellent domain fidelity but also in a smoother surface morphology, as it is shown in the cross section (FIG. 5A) and top surface (FIG. 5B) images compared with the growths of OP-GaAsP grown on the conventional OP-GaAs templates with an encapsulating layer (FIG. 5C).

The following examples illustrate particular properties and advantages of some of the embodiments of the present invention. Furthermore, these are examples of reduction to practice of the present invention and confirmation that the principles described in the present invention are therefore valid but should not be construed as in any way limiting the scope of the invention.

HVPE growth methods have been developed to make the proposed OP-GaP, OP-GaAs, and OP-GaAsP QPM structures that may be used in frequency conversion processes, specifically using an optical parametric oscillators (OPO) (see FIG. 7). An OPO is formed when the nonlinear crystal is placed inside an optical cavity. The presence of resonator feedback allows for greater depletion of the pump beam and higher conversion efficiencies compared to the non-resonant OPA or OPG processes for similar input energies. In an OPO, the gain comes from instantaneous parametric generation in a nonlinear crystal such as the QPM structure.

ALTERNATIVE VARIATIONS

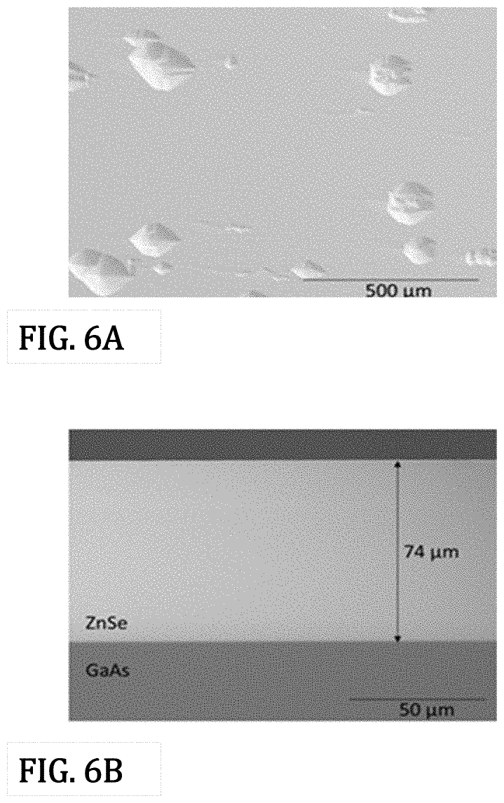

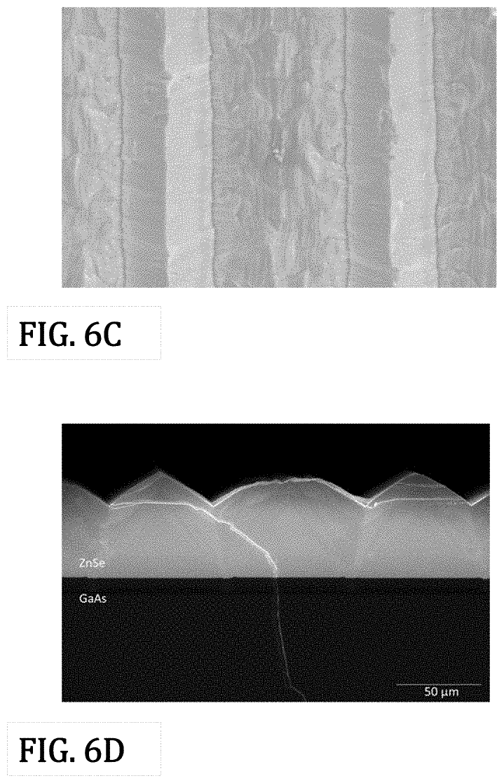

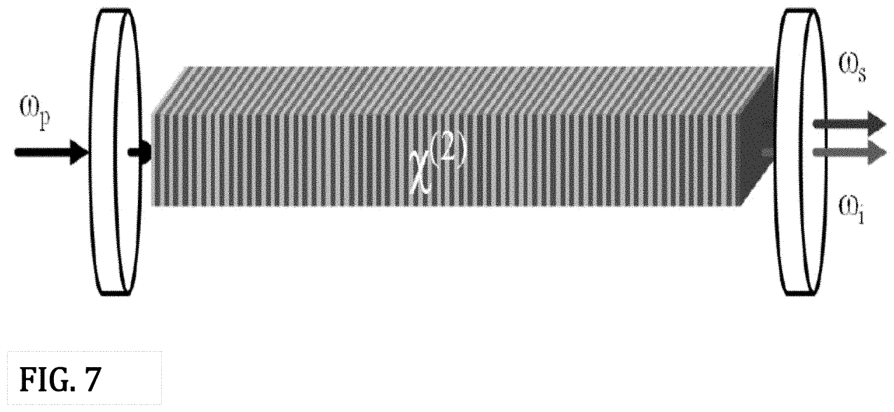

OP-GaP QPM structure growth has been achieved on OP-GaAs templates; the pattern deposited on the inverted layer was not encapsulated by a MBE GaAs encapsulating layer prior to the HVPE growth. Recently, OP-ZnSe has also been grown on the same OP-GaAs templates without an encapsulating MBE layer. FIG. 6A presents a top surface SEM image of ZnSe grown on a GaAs substrate. FIG. 6B presents a cross sectional SEM image of ZnSe grown on a GaAs substrate. FIG. 6C presents a top surface SEM image of OP-ZnSe grown on an OP-GaAs template without an encapsulating layer. FIG. 6D presents a cross sectional SEM image of OP-ZnSe grown on an OP-GaAs template without an encapsulating layer. The growth conditions for the HVPE growth of ZnSe on GaAs substrates and OP-GaAs template are similar to the growth conditions of the other materials mentioned in this disclosure. In particular, a substrate temperature between 500-850 ° C., reactor pressure under 10 Ton and total gas flow less than 250 sccm. The main difference is that in the growth of ZnSe and OP-ZnSe, Zn-metal and hydrogen selenide (H₂Se) are used instead using molten Ga and AsH₃ or PH₃.

Unlike the prior art, QPM design is tolerant with the inverted layer-only templates—meaning that while the design or pattern is embedded permanently with prior art methods that require MBE regrowth, eliminating the MBE regrowth step allows design flexibility up until template fabrication.

This new approach for the fabrication of OP-templates without an encapsulating layer, and the growth on such templates, as well as the combinations of materials and growth techniques used in these processes will broaden the range of frequency conversion devices to realize new wavelengths in the mid and longwave infrared (MLWIR) region suitable for many new commercial and military applications.

While the present invention has been illustrated by a description of one or more embodiments thereof and while these embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

What is claimed is:

1. A method of performing heteroepitaxy, comprising:
exposing an OP-GaAs template in an HVPE reactor to
a carrier gas,
a first precursor gas,
a second precursor gas (2pg),
a Group II element, and
a third precursor gas (3pg), to form an epitaxial growth of one of GaAs, GaP,
and GaAsP directly on the OP-GaAs template;
wherein the carrier gas is H₂,
wherein the first precursor gas is HCl,
the Group II element is Ga; and
wherein the second and the third precursor gas (V group) is one or more of AsH₃ (arsine) and PH₃ (phosphine), or their mixture.

2. The method of claim 1, further comprising:
for an epitaxial growth of GaAsP, flowing the second and third precursor gases of AsH₃ (arsine) and PH₃ (phosphine), respectively, through the HVPE reactor at a 2pg:3pg ratio of about 1:0;
heating the OP-template to 500° C.-900° C.; and
gradually changing the 2pg:3pg ratio toward 0:1 over a time period of 1 min-10 hours.

3. The method of claim 2, wherein heating the OP-template to 700° C.-740° C.

4. The method of claim 1, further comprising:
for an epitaxial growth of GaAs, flowing the second and third precursor gases of AsH₃ (arsine) through the HVPE reactor;
heating the OP-template to 500° C.-900° C.; and
maintaining the growth conditions for a desired time period.

5. The method of claim 4, wherein heating the OP-template to 700° C.-740° C.

6. The method of claim 1, further comprising: for an epitaxial growth of GaP, flowing the second and third precursor gases of PH₃ (phosphine) through the HVPE reactor;
heating the OP-template to 500° C.-900° C.; and
maintaining the growth conditions for a desired time period. The method of claim 6, wherein heating the OP-template to 700° C.-740° C.

8. A method of performing heteroepitaxy, comprising:
exposing an OP-GaAs template in an HVPE reactor to
a carrier gas,
a first precursor gas,
a second precursor gas,
a Group II element to form an epitaxial growth of ZnSe directly on the OP-GaAs template;
wherein the carrier gas is H₂,
wherein the first precursor is HCl,
the Group II element is Zn; and
wherein the second precursor is H₂Se (hydrogen selenide).

9. The method of claim 8, wherein heating the OP-template to 500° C.-850° C.

10. An epitaxial structure comprising:
an (orientation-patterned) OP-GaAs template having a face of exposed OP-GaAs; and
an epitaxially-grown layer of a semiconductor directly on the exposed OP-GaAs of the OP-GaAs template, wherein the semiconductor is one or more of GaAs, GaP, GaAsP, and ZnSe.
